(19) United States
(12) Patent Application Publication
(10) Pub. No.: US 2020/0273804 A1
(43) Pub. Date: Aug. 27, 2020

(54) SEMICONDUCTOR DEVICES HAVING CONDUCTIVE PILLARS AND METHODS OF MANUFACTURING THE SAME

(71) Applicant: Samsung Electronics Co., Ltd., Suwon-si (KR)

(72) Inventors: Gwang Jae JEON, Hwaseong-si (KR); Dong Kyu Kim, Anyang-si (KR); Jung Ho PARK, Cheonan-si (KR); Yeon Ho JANG, Goyang-si (KR)

(21) Appl. No.: 16/567,790

(22) Filed: Sep. 11, 2019

(30) Foreign Application Priority Data
Feb. 22, 2019 (KR) 10-2019-0021100

(51) Int. Cl. H01L 23/538; H01L 25/10; H01L 23/00; H01L 23/31; H01L 21/683; H01L 21/48; H01L 21/56

(52) U.S. Cl. CPC H01L 23/5389; H01L 2221/68372; H01L 24/20; H01L 23/3128; H01L 23/5383; H01L 23/5386; H01L 24/19; H01L 21/6835; H01L 21/4857; H01L 21/4853; H01L 21/4864; H01L 21/568; H01L 21/565; H01L 2225/1035; H01L 2225/1058; H01L 2224/214; H01L 25/105

(57) ABSTRACT

A semiconductor package includes a first redistribution structure, a first semiconductor chip disposed on the first redistribution structure, a plurality of conductive pillars disposed on the first redistribution structure, an encapsulant covering an upper surface of the first redistribution structure, and a second redistribution structure disposed on the encapsulant. The encapsulant has an upper surface having openings that expose upper surface of the plurality of conductive pillars. The second redistribution structure includes a wiring pattern and connection vias connecting the wiring pattern to the plurality of conductive pillars. An inner side surface of an opening extends vertically from a side surface of the conductive pillar.

### CROSS-REFERENCE TO THE RELATED APPLICATION

This U.S. non-provisional patent application claims priority under 35 U.S.C. § 119 to and the benefit of Korean Patent Application No. 10-2019-0021100, filed on Feb. 22, 2019, in the Korean Intellectual Property Office (KIPO), the disclosure of which is incorporated herein by reference in its entirety.

### BACKGROUND

### 1. Field

The present inventive concept relates to a semiconductor package having a conductive pillar and a method of manufacturing the same.

### 2. Description of Related Art

As semiconductor devices are becoming highly integrated, a technique for integrating and miniaturizing a semiconductor chip and a semiconductor package on which the semiconductor chip is mounted is being highlighted. In order to manufacture a thin semiconductor package, a fan-out wafer-level packaging technology in which a redistribution layer is formed below a semiconductor chip instead of a printed circuit board has been developed. Meanwhile, as the semiconductor chip is becoming miniaturized, an interval between solder balls is reduced so that there is a problem in that handling of the solder balls becomes difficult. In order to address this problem, fan-out wafer-level packaging has been proposed.

### SUMMARY

The present inventive concept is directed to providing a method of manufacturing a semiconductor package. The process may assist in removing a residue generated during a grinding process.

A semiconductor package according to exemplary embodiments of the present inventive concept includes a first redistribution structure, a first semiconductor chip disposed on the first redistribution structure, a conductive pillar disposed on the first redistribution structure and being adjacent to the first semiconductor chip, an first encapsulant covering an upper surface of the first redistribution structure, a lower surface and side surfaces of the first semiconductor chip, and side surfaces of the conductive pillar, the encapsulant having an upper surface having openings formed therein, the openings exposing upper surfaces of the conductive pillar, and a second redistribution structure disposed on the first encapsulant and connected to the conductive pillar, wherein the second redistribution structure comprises a wiring pattern and connection vias, the connection vias filling at least a portion of the openings and connected to the conductive pillar. The openings expose a portion of the first redistribution structure.

A semiconductor package according to exemplary embodiments of the present inventive concept includes a first redistribution structure, a first semiconductor chip disposed on the first redistribution structure, a plurality of conductive pillars disposed on the first redistribution structure and being adjacent to the first semiconductor chip, an encapsulant covering an upper surface of the first redistribution structure, the first semiconductor chip, and side surfaces of the plurality of conductive pillars, the encapsulant having an upper surface having openings formed therein, the openings exposing upper surfaces of the plurality of conductive pillars, and a second redistribution structure disposed on the encapsulant and connected to the plurality of conductive pillars. The second redistribution structure comprises a wiring pattern and connection vias formed on the wiring pattern, the connection vias connected to the plurality of conductive pillars. A height from an upper surface of the first redistribution structure to an upper surface of the encapsulant is higher than a height from the upper surface of the first redistribution structure to an upper surface of at least one of the plurality of the conductive pillars.

A method of manufacturing a semiconductor package according to exemplary embodiments of the present inventive concept includes forming a first redistribution structure on a first carrier, forming a plurality of conductive pillars on the first redistribution structure, mounting a first semiconductor chip on the first redistribution structure to be adjacent to the plurality of conductive pillars, forming an encapsulant configured to cover an upper surface of the first redistribution structure, the plurality of conductive pillars, and the first semiconductor chip, grinding the plurality of conductive pillars and the encapsulant so that an upper surface of the first semiconductor chip is exposed, removing a residue generated in the grinding process, and forming a second redistribution structure connected to the plurality of conductive pillars.

### BRIEF DESCRIPTION OF THE DRAWINGS

The above and other objects, features, and advantages of the present inventive concept will become more apparent to those of ordinary skill in the art by describing exemplary embodiments thereof in detail with reference to the accompanying drawings, in which:

FIGS. 1 to 7, 9, 10, and 12 to 15 are cross-sectional views shown in accordance with a process sequence for describing a method of manufacturing a semiconductor package according to one exemplary embodiment of the present inventive concept.

FIG. 8 is a partially enlarged view of the semiconductor package shown in FIG. 7.

FIG. 11 is a partially enlarged view of the semiconductor package shown in FIG. 10.

FIGS. 16 to 18 are cross-sectional views of a semiconductor package according to another embodiment of the present inventive concept.

FIGS. 19 to 22 are cross-sectional views that are shown according to a process sequence for describing a method of manufacturing the semiconductor package according to one exemplary embodiment of the present inventive concept.

FIG. 23 is a partially enlarged view of the semiconductor package shown in FIG. 22.

FIG. 24 is a cross-sectional view of a semiconductor package according to another embodiment of the present inventive concept

### DETAILED DESCRIPTION OF EXEMPLARY EMBODIMENTS

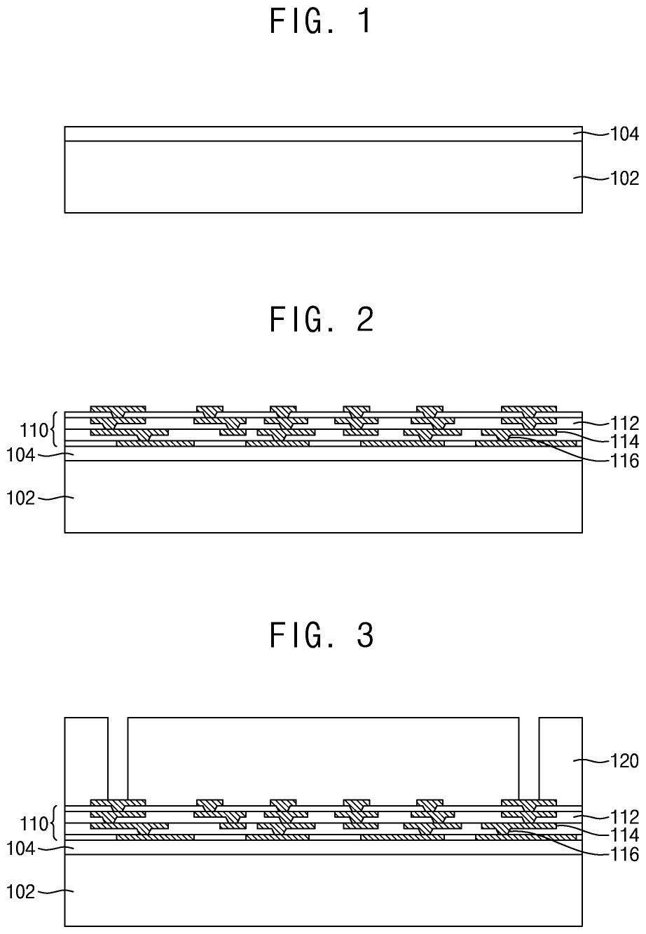

FIGS. 1 to 7, 9, 10, and 12 to 15 are cross-sectional views shown in accordance with a process sequence for describing a method of manufacturing a semiconductor package according to one exemplary embodiment of the present inventive concept.

The method of manufacturing the semiconductor package according to one exemplary embodiment of the present inventive concept may include providing a first carrier, forming a first redistribution structure on the first carrier, forming a conductive pillar on the first redistribution structure, mounting a first semiconductor chip on the first redistribution structure, forming an encapsulant covering an upper surface of the first redistribution structure, a plurality of conductive pillars, and the first semiconductor chip, grinding the plurality of conductive pillars and the encapsulant so that an upper surface of the first semiconductor chip is exposed, removing residues generated in the grinding process, and forming a second redistribution structure connected to the plurality of conductive pillars on the first semiconductor chip and the encapsulant. Further, the method of manufacturing the semiconductor package according to one exemplary embodiment of the present inventive concept may further include mounting a second semiconductor chip on the second redistribution structure and forming an encapsulant covering an upper surface of the second redistribution structure and the second semiconductor chip.

Hereinafter, a method of manufacturing a semiconductor package 100 according to the exemplary embodiment of the present inventive concept configured as described above will be described with reference to FIGS. 1 to 15.

Referring to FIG. 1, a process of providing a first carrier 102 is performed. A release film 104 may be disposed on the first carrier 102. The first carrier 102 may be a glass carrier, a ceramic carrier, a silicon wafer, or the like. The release film 104 may be composed of multiple layers and may include, for example, an adhesive layer and a release layer. The release film 104 may serve to bond a structure to be formed thereon to the first carrier 102. Further, the release film 104 may be removed together with the first carrier 102 from an upper structure which will be described below and may include a polymer-based material. In one exemplary embodiment, the release film 104 may include a light-to-heat-conversion (LTHC) release coating material and may be thermally released by heating. In another exemplary embodiment, the release film 104 may include an ultraviolet (UV) adhesive which is released by UV light. Further, the release film 104 may be released by a physical method. The release film 104 may be applied in a liquid or cured state or may be a laminate film laminated on the first carrier 102. An upper-end surface of the release film 104 may be flattened and may have a high coplanarity.

Referring to FIG. 2, a process of forming a first redistribution structure 110 on the first carrier 102 is performed. For example, the first redistribution structure 110 may be disposed on the release film 104. The first redistribution structure 110 may be composed of a plurality of layers. Each layer of the first redistribution pattern 110 may include an interlayer insulating layer 112 and a wiring pattern 114. The first redistribution structure 110 may further include a via 116.

The vias 116 may electrically connect respective wiring patterns 114 of different layers of the redistribution layer 110. Vias 116 may have a cylindrical shape as well as a tapered shape. Further, vias 116 may be formed integral and homogenous (e.g., formed of all or some of the same conductive material layers) as the wiring pattern 114. The interlayer insulating layer 112 may electrically insulate various wiring patterns 114 and vias 116 from each other and from the outside. Thus, the first redistribution structure 110 may include a plurality of wires (each wire being formed by connecting several wiring patterns 114 of different layers of the redistribution structure 110 with corresponding vias 116) providing electrical signal paths or electrical power paths from one location on a bottom of the first redistribution structure 110 to another location at a top of the first redistribution structure 110. Although FIG. 2 illustrates the locations of such wires to be formed within the same vertical cross section of the redistribution structure 110, this is for purposes of explanation; wiring patterns 114 may extend in different directions (such as in and out of the page of FIG. 2, more extensively in left and right directions with respect to FIG. 2 and/or in horizontal directions oblique to such directions) so that termination points of wiring (e.g., terminals of electrical signal and power paths formed by the redistribution structure) at top and bottom surfaces of the redistribution structure need not correspond to each other and may be positioned based on various design criteria of the semiconductor package and semiconductor chips encapsulated therein.

The interlayer insulating layer 112 may be a photosensitive material that may be patterned using a photolithography process. For example, the interlayer insulating layer 112 may be a polymer such as polybenzoxazole (PBO), polyimide, benzocyclobutene (BCB), or the like. In another exemplary embodiment, the interlayer insulating layer 112 may include at least one selected from silicon nitride, silicon oxide, phosphosilicate glass (PSG), borosilicate glass (BSG), and boron-doped phosphosilicate glass (BPSG). The interlayer insulating layer 112 may be formed by a process such as a chemical vapor deposition (CVD) process, a lamination process, a spin coating process, or the like.

The process of forming the first redistribution structure 110 may include a process of forming one or more wiring patterns 114 on the release film 104. The process of forming a wiring pattern 114 may include a damascene process including forming a patterned interlayer insulating layer 112 (an insulating layer patterned to include openings formed therein), and forming a wiring layer 114 by depositing one or more conductive layers (e.g., a barrier layer and another conductor layer) on the patterned interlayer insulating layer 112 (e.g., via CVD) and planarizing the resultant structure to expose the top surface of the patterned interlayer insulating layer 112 to form discrete wiring patterns 114 in the openings of the patterned interlayer insulating layer 112. In some examples, the first redistribution structure 110 may be formed by selectively forming the wiring patterns within openings of a mold structureon the release film 104 or on a corresponding interlayer insulating layer 112. For example, forming the first redistribution structure 110 may include forming a barrier layer and a seed layer (not shown) on the top surface of the release film 104 or on a corresponding interlayer insulating layer 112, a process of forming a patterned mask (not shown) such as a photoresist or the like on the seed layer, and a process of selectively forming a conductive material on the exposed seed layer within openings of the patterned mask. The process of selectively forming the conductive material may include a plating process (e.g., electroplating, such as by immersing the structure (first carrier 102, release film 104, patterned photoresist, interlayer insulating film 112, etc.) in a solution (e.g., an electrolyte bath) containing one or more metal ions that are plated onto exposed (and charged) seed layer). Thereafter, the patterned mask and portions of the barrier layer and the seed layer which are covered by the patterned mask are removed to form the wiring pattern 114. As shown in FIG. 2, the first redistribution structure 110 may be formed by repeating such processes of forming a wiring pattern 114 and vias 116 after covering a previously formed wiring pattern 114 and via 116 with a new interlayer insulating layer 112.

The barrier layer may include and/or be at least one selected from tantalum (Ta), titanium (Ti), tungsten (W), ruthenium (Ru), vanadium (V), cobalt (Co), and niobium (Nb). The seed layer may include and/or be at least one selected from aluminum (Al), Ti, chromium (Cr), iron (Fe), Co, nickel (Ni), copper (Cu), zinc (Zn), palladium (Pd), platinum (Pt), gold (Au), and silver (Ag). In one exemplary embodiment, the barrier layer may be Ti, and the seed layer may be Cu. The barrier layer and the seed layer may be formed by a physical vapor deposition (PVD) process, a CVD process, an atomic layer deposition (ALD) process, or the like.

The wiring pattern 114 and the via 116 may include and/or be at least one metal selected from Al, Ti, Cr, Fe, Co, Ni, Cu, Zn, Pd, Pt, Au, and Ag. In one exemplary embodiment, the wiring pattern 114 and the via 116 are formed of Cu. The wiring pattern 114 and the via 116 may be formed by an electrochemical plating process, an electroless plating process, a PVD process, a CVD process, a spin-on process, or a combination thereof. In one exemplary embodiment, the wiring pattern 114 and the via 116 are integrally formed from the same one or more layers by a damascene process.

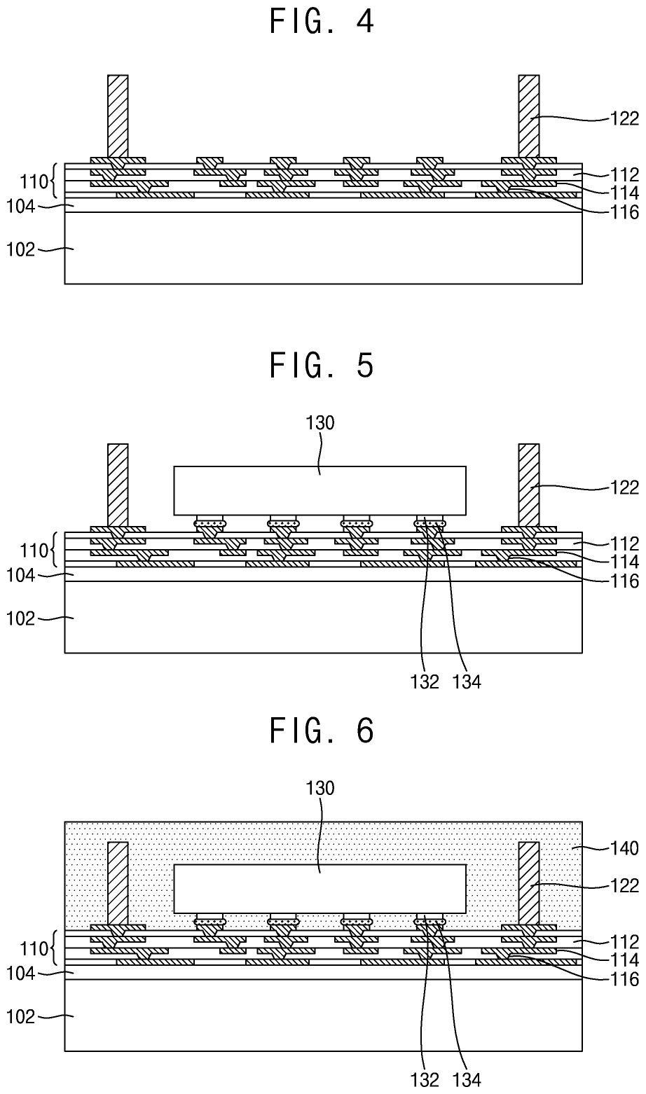

Referring to FIGS. 3 and 4, a process of forming a conductive pillar 122 on the first redistribution structure 110 is performed. For example, a plurality of conductive pillars 122 may be disposed on the first redistribution structure 110 by a plating process. The plurality of conductive pillars 122 may be disposed on the wiring pattern 114 of an uppermost layer of the first redistribution structure 110.

Referring to FIG. 3, a mask pattern 120 may be disposed on an upper surface of the first redistribution structure 110. A portion of the upper surface of the first redistribution structure 110 may be exposed by the mask pattern 120. For example, the wiring pattern 114 to be connected to the conductive pillar 122 may be exposed by the mask pattern 120. Referring to FIG. 4, the conductive pillar 122 may be disposed on the portion of the upper surface of the first redistribution structure 110 which is exposed by the mask pattern 120.

The process of forming of the conductive pillar 122 may include a process of forming a barrier layer and a seed layer (not shown), a process of forming the mask pattern 120 on the seed layer, and a process of filling the portion exposed by the mask pattern 120 with a conductive material. Thereafter, the mask pattern 120 and portions of the barrier layer and the seed layer (which are covered by the mask pattern 120) may be removed.

Although not shown, the barrier layer and the seed layer may be formed on the upper surface of the first redistribution structure 110. In one exemplary embodiment, the barrier layer is formed from Ti, and the seed layer is formed of Cu. The barrier layer and the seed layer may be formed by a PVD process, a CVD process, an ALD process, or the like.

The mask pattern 120 may be formed on the seed layer. The mask pattern 120 may be formed by a spin coating process or the like and may be exposed to light for patterning. The mask pattern 120 may define a region in which the conductive pillar 122 is to be disposed. The conductive material may be formed in an opening of the mask pattern 120 and on the exposed portion of the seed layer. The conductive material may be formed, for example, by plating such as electroplating, electroless plating, or the like. The conductive material may include a metal such as Cu, Ti, W, Al, or the like. In one exemplary embodiment, the conductive material may include Cu. The mask pattern 120 and a portion of the seed layer, on which the conductive material is not formed, may be removed. The mask pattern 120 may be removed by a release process in which an oxygen plasma or the like is used. After the mask pattern 120 is removed, the exposed portions of the barrier layer and the seed layer may be removed by wet or dry etching. Remaining portions of the barrier layer and the seed layer, and the conductive material may form the conductive pillar 122.

Referring to FIG. 5, a process of mounting a first semiconductor chip 130 on the first redistribution structure 110 is performed. For example, the first semiconductor chip 130 may be positioned to be adjacent to the conductive pillar(s) 122. The plurality of conductive pillars 122 may be disposed to surround the first semiconductor chip 130 when viewed from above.

The first semiconductor chip 130 may include bonding pads 132 (e.g., chip pads) and have conductive bumps 134 disposed thereon. The bonding pads 132 may be electrically connected to corresponding wiring patterns 114 of the first redistribution structure 110 through the bump 134. For example, many of the bonding pads 132 of the first semiconductor chip 130 may be connected to a respective wiring pattern formed between one surface of the first redistribution structure 110 to the opposite surface of first redistribution structure 110. In one exemplary embodiment, the bonding pad 132 may be formed of Cu, and the bump 134 may be formed of tin (Sn).

An upper surface of the conductive pillar 122 after its initial formation may be positioned at a higher level than an upper surface of the first semiconductor chip 130. In FIG. 5, the first semiconductor chip 130 is shown as being flip-chip bonded on the first redistribution structure 110 (with its active surface facing the first redistribution structure 110), but the present inventive concept is not limited thereto, and the first semiconductor chip 130 may be connected to the first redistribution structure 110 by wire bonding. When the first semiconductor chip 130 is wire-bonded, the upper surface of the conductive pillar 122 may be positioned at a higher level than the upper surface of the first semiconductor chip 130.

Referring to FIG. 6, a process of forming an encapsulant 140 covering the upper surface of the first redistribution structure 110, the plurality of conductive pillars 122, and the first semiconductor chip 130 is performed. In one exemplary embodiment, the encapsulant 140 may be formed by a molded underfill method and may fill a space between the upper surface of the first redistribution structure 110 and a lower surface of the first semiconductor chip 130. In another exemplary embodiment, an underfill may be formed between the upper surface of the first redistribution structure 110 and the lower surface of the first semiconductor chip 130 before the encapsulant 140 is formed. The encapsulant 140 may protect the conductive pillar 122 and the first semiconductor chip 130 from external influences such as impacts or the like.

The encapsulant 140 may be formed of at least one resin such as an epoxy or polyimide. For example, the encapsulant 140 may include a bisphenol-group epoxy resin, a polycyclic aromatic epoxy resin, an o-cresol novolac epoxy resin, a biphenyl-group epoxy resin, a naphthalene-group epoxy resin, or the like.

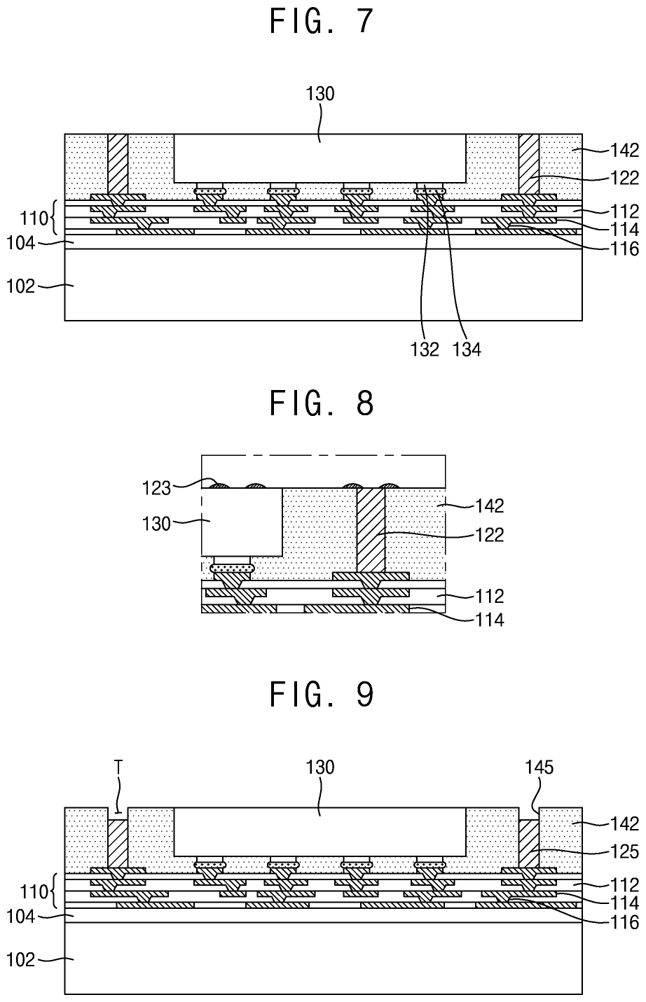

Referring to FIG. 7, a process of grinding the plurality of conductive pillars 122 and the encapsulant 140 such that the upper surface of the first semiconductor chip 130 is exposed is performed. The encapsulant 140 may be ground to form encapsulant 142 (see FIG. 7). In the exemplary embodiment, encapsulant 142 is a modified form of encapsulant 140 after the process of grinding is completed. An upper portion of the conductive pillar 122 may be partially removed by the grinding process. After the grinding process, the upper surface of the conductive pillar 122, the upper surface of the first semiconductor chip 130, and an upper surface of the encapsulant 142 may be positioned at the same level. It will be clear that “same level” (and other similar descriptions) does not require exactly the same level but may include acceptable variations that may occur during conventional manufacturing process. The term “substantially” may be used herein to emphasize this meaning.

FIG. 8 is a partially enlarged view of the semiconductor package shown in FIG. 7. Referring to FIG. 8, residues 123 of the upper portions of the conductive pillars 122, which are partially removed by the grinding process, may be disposed on the resultant structure of FIG. 7. In one exemplary embodiment, the residues 123 may be formed by the conductive pillars 122 being pushed by stress, and the residues 123 may be disposed on the conductive pillar 122, for example. In one exemplary embodiment, the residues 123 that are separated from the conductive pillar 122 may be disposed on the upper surface of the first semiconductor chip 130 or the encapsulant 142. When the residues 123 are generated, reliability of a device may be lowered, and/or the device may be contaminated and/or defective. Further, a cross section of the conductive pillar 122 may not be uniform when viewed from above so that utilization of the conductive pillar 122 as an align-key may be restricted.

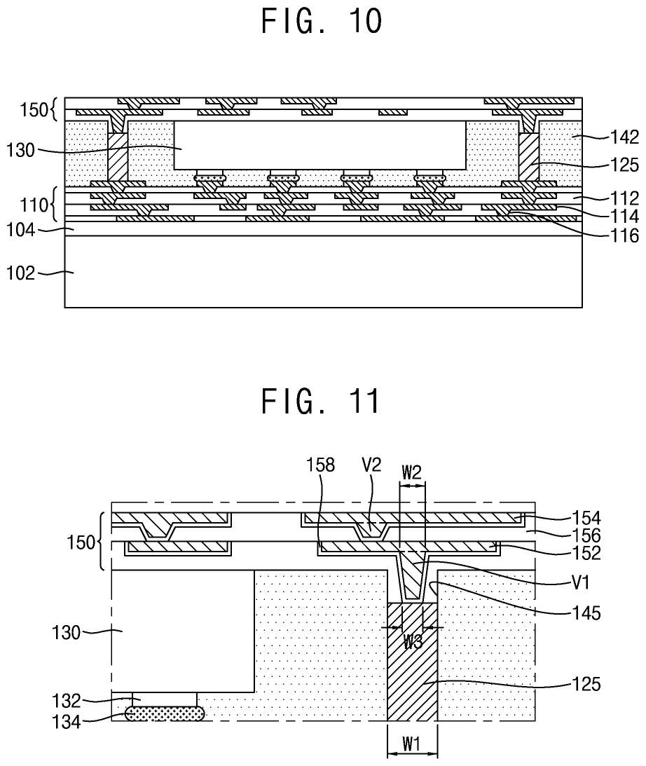

Referring to FIG. 9, a process of removing the residues 123 is performed. For example, the residues 123 may be removed by selective etching. An upper portion of the conductive pillar 122 may also be partially removed to form a conductive pillar 125. Conductive pillar 125 is conductive pillar 122 in modified form after a top portion of conductive pillar 122 is removed. During the removal process, a top portion of conductive pillar 122 may be partially removed and thereby an opening OP is formed in an upper portion of the encapsulant 142. The opening OP in the upper portion of encapsulant 142 may take other shapes such as a conventional via shape (circular, square, rectangular, etc.). As illustrated by FIG. 9, an inner side surface 145 of the opening OP is delineated by a portion of the encapsulant 142, and a lower surface of the opening OP is delineated by an upper surface of the conductive pillar 125. It will be understood that with respect to opening OP, the dimensions of opening OP may be delineated by boundaries of a portion of the encapsulant and an upper surface of the conductive pillar, and, e.g., opening OP may be described as “having” and/or “including” these delineated boundaries and/or attributes for ease of understanding and explanation. The upper surface of the conductive pillar 125 may be positioned at a lower level than the upper surface of the first semiconductor chip 130 and/or the upper surface of the encapsulant 142. For example, a height from an upper surface of the first redistribution structure 110 to an upper surface of the conductive pillars 125 may be lower than a height from the upper surface of the first redistribution structure 110 to an upper surface of the first semiconductor chip 130. A height from the upper surface of the first redistribution structure 110 to an upper surface of the encapsulant 142 may be higher than a height from the upper surface of the first redistribution structure 110 to an upper surface of at least one of the plurality of the conductive pillars 125.

In one exemplary embodiment, the conductive pillar 125 may be removed by wet etching using a wet etchant. For example, the wet etchant may include and/or be at least one chosen from an alkaline etchant such as FeCl₃, CuCl₂, and Cu(NH₃)₄²⁺, H₂O₂—H₂SO₄, CrO₃—H₂SO₄, and NaClO₃. In other embodiments, the first semiconductor chip 130 and the encapsulant 142 may not be etched in the above-described etching process. In some embodiments, a plurality of conductive pillars 125 are formed on the first redistribution structure 110, and the plurality of conductive pillars 125 are etched by one process when the wet etching is performed. Therefore, in this embodiment a manufacturing process of the semiconductor package may be simplified, and yield may be easily secured.

As shown in FIG. 9, the problems associated with residues 123 causing reduced reliability may be mitigated and/or prevented by removing residues 123. In addition, when viewed from above, since a width W1 of the conductive pillar 125 may be formed to correspond to a design value, the conductive pillar 125 may be utilized as an align-key in subsequent processes.

Referring to FIG. 10, a process of forming a second redistribution structure 150 connected to the conductive pillar 125 on the encapsulant 142 is performed. A detailed description of a configuration of the second redistribution structure 150 similar to or the same as that of the first redistribution structure 110 may be omitted.

FIG. 11 is a partially enlarged view of the semiconductor package shown in FIG. 10. Referring to FIG. 11, the second redistribution structure 150 may include a first wiring pattern 152, a second wiring pattern 154, and an interlayer insulating layer 156. The second redistribution structure 150 may further include a connection vias V1 and connection vias V2. The first wiring pattern 152 may be disposed on the connection vias V1. The second redistribution structure 150 may be composed of a plurality of layers. The second redistribution structure may be formed to include wiring pattern(s) and layer(s) similar to the first redistribution structure 110. The second redistribution structure 150 may fill the inside of the opening OP. Specifically, the first wiring pattern may extend into opening OP and contact the conductive pillars 125.

The interlayer insulating layer 156 may be formed on the first semiconductor chip 130 and the encapsulant 142. The interlayer insulating layer 156 may be patterned to provide holes and/or openings therein that define positions at which the first wiring pattern 152 and the connection via V1 are formed. The interlayer insulating layer 156 may be disposed between the inner side surfaces 145 of at least one of the openings OP and the connection via V1 filling the at least one openings OP. A barrier layer 158 may be conformally formed on and in contact with the interlayer insulating layer 156 and the conductive pillar 125. The conductor (not labelled) of the first wiring pattern 152 and the connection via V1 may be formed by depositing a conductive material (e.g., metal) on the resultant structure (e.g., on and in contact with the barrier layer 158) filling the remaining portions of openings of the pattern of the interlayer insulating layer 156. The barrier layer 158 may be a component of the first wiring pattern 158 and the connection via V1. A portion of the barrier layer 158 surrounding the first wiring pattern 158 may be integrally formed with a portion of the barrier layer 158 surrounding the connection via V1. The first wiring pattern 152, the second wiring pattern 154, the connection via V1, and the via V2 may be formed by a process such as a CVD process, an ALD process, a plating process, or the like. The barrier layer 158 may be formed of a material including at least one selected from Ta, Ti, W, Ru, V, Co, and Nb. The barrier layer 158 may include a seed layer, and the seed layer may include and/or be at least one selected from Al, Ti, Cr, Fe, Co, Ni, Cu, Zn, Pd, Pt, Au, and Ag. In one exemplary embodiment, the barrier layer 158 may include and/or be Ti, and the seed layer may include and/or be Cu.

The connection via V1 may connect the first wiring pattern 152 to the conductive pillar 125. The first wiring pattern 152 and the connection via V1 may be integrally formed. The connection via V1 may be an element of the first wiring pattern 152. For example, the conductor of first wiring pattern 152 and the connection via V1 may be formed by a damascene process. The connection via V1 may have a truncated conical shape. An upper surface of the connection via V1 may be positioned at a higher level than the upper surface of the encapsulant 142, and the lower surface of the connection via V1 may be positioned at a lower level than the upper surface of the encapsulant 142. In one exemplary embodiment, the connection via V1 may partially fill the opening OP. For example, a width of the opening OP may be greater than a width W2 of the upper surface of the connection via V1. Further, the width of the opening OP may be greater than a width W3 of the lower surface of the connection via V1. In the connection via V1, the width W2 of the upper surface may be greater than the width W3 of the lower surface. The width of the opening OP may be substantially the same as the width W1 of the conductive pillar 125. The via V2 may electrically connect the first wiring pattern 152 and the second wiring pattern 154, which are positioned on different layers, to each other.

In the method of manufacturing the semiconductor package according to one exemplary embodiment of the present inventive concept, the opening OP may be formed by partially removing an upper portion of the conductive pillar 125. Accordingly, the inner side surface 145 of the opening OP may be coplanar (e.g., substantially coplanar including acceptable variations resulting from conventional manufacturing processes) with a side surface of the conductive pillar 125. For example, an inner side surface of the opening OP may extend vertically from a side surface of the conductive pillar 125.

As illustrated by the exemplary embodiment, the inner side surface 145 of the opening OP and the side surface of the conductive pillar 125 may be formed in a vertical direction. Here, the vertical direction may mean a direction orthogonal to the upper surface of the first semiconductor chip 130. In another exemplary embodiment, the inner side surface 145 of the opening OP and the side surface of the conductive pillar 125 may be formed to be inclined with respect to the vertical direction. For example, an inner side surface of the opening OP may extend outward at an angle that corresponds to the inclination of the conductive pillar 125.

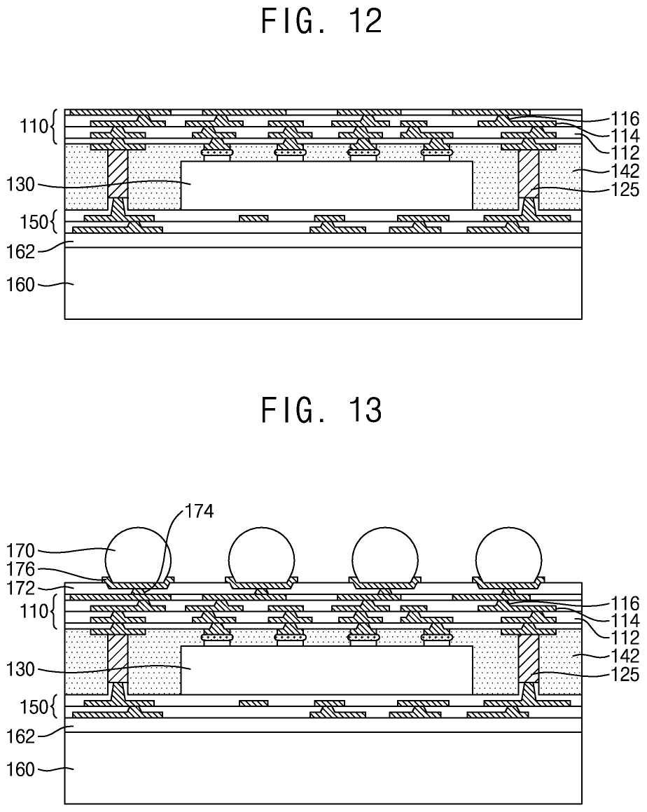

Referring to FIG. 12, the first carrier 102 (see FIGS. 2-9) may be separated from the first redistribution structure 110 and a second carrier 160 may be formed on the second redistribution structure 150. The first carrier 102 may be separated by a debonding process of the release film 104 while the resultant shown in FIG. 10 is inverted. In one exemplary embodiment, the debonding process may include a process of projecting light, such as laser light or UV light, onto the release film 104. The release film 104 may be pyrolyzed by heat of the light, and the first carrier 102 may be separated from the first redistribution structure 110.

The second carrier 160 may be formed before the first carrier 102 is separated. A release film 162 may be further disposed between the second carrier 160 and the second redistribution structure 150. The second carrier 160 may be positioned on a surface of the second redistribution structure 150 opposite to the surface in contact with the first semiconductor chip 130. The second carrier 160 and the release film 162 may include the same material as the first carrier 102 and the release film 104, respectively.

Referring to FIG. 13, external connection members 170 may be formed on the first redistribution structure 110. The external connection member 170 may be disposed on a surface of the first redistribution structure 110 opposite to the surface on which the first semiconductor chip 130 is mounted. The external connection member 170 may be connected to the wiring pattern 114 of the first redistribution structure 110 by a via 174 and an under bump metal 176. An interlayer insulating layer 172 may be disposed on the wiring pattern 114 of the first redistribution structure 110 and may cover the wiring pattern 114 and the via 174. The under bump metal 176 may be disposed on the interlayer insulating layer 172.

The external connection member 170 may include at least one element chosen from Sn, Ag, Cu, Pd, Bi, and Sb. The interlayer insulating layer 172 may be the same material as the interlayer insulating layer 112 and may be formed from, for example, a polymer such as PBO, polyimide, BCB, or the like. The via 174 may include at least one metal chosen from Al, Ti, Cr, Fe, Co, Ni, Cu, Zn, Pd, Pt, Au, and Ag. In one exemplary embodiment, the via 174 may be Cu. The under bump metal 176 may include at least one chosen from chromium/chromium-copper alloy/copper (Cr/Cr—Cu/Cu), titanium-tungsten alloy/copper (Ti—W/Cu), aluminum/nickel/copper (Al/Ni/Cu), and nickel. The under bump metal 176 may be formed by a sputtering process, an electrolytic plating process, an electroless plating process, or the like.

Referring to FIGS. 5 to 9, although not shown, a plurality of first semiconductor chips 130 may be arranged on the first carrier 102, e.g., spaced apart at regular intervals. A plurality of conductive pillars 125 may be disposed adjacent to (e.g., surrounding) each of these first semiconductor chips 130. In some embodiments, a singulation process, such as a sawing process, may be further performed after the external connection members 170 are formed to separate the first semiconductor chips 130 from one another.

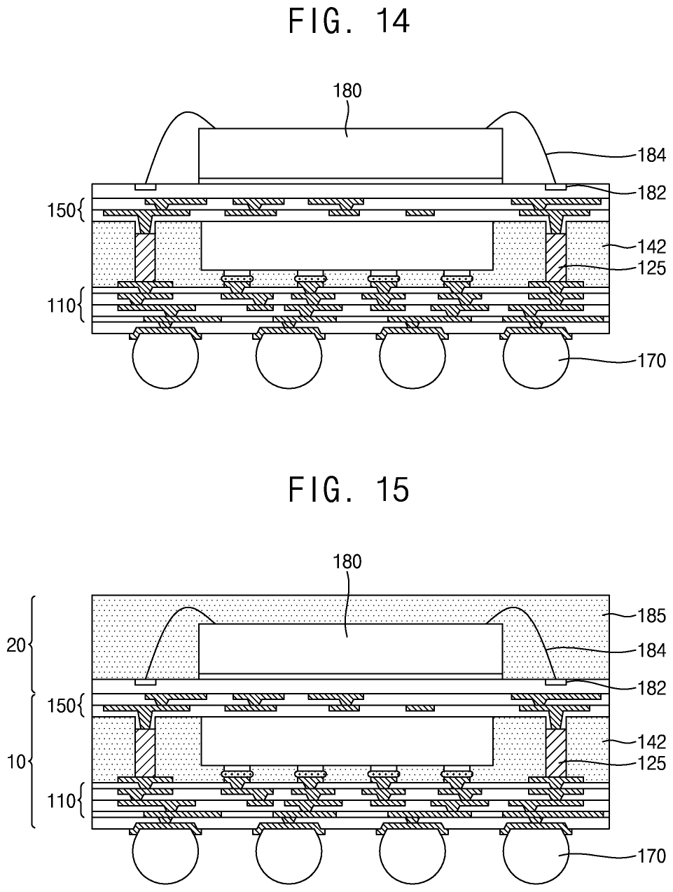

Referring to FIG. 14, a second semiconductor chip 180 may be mounted on the second redistribution structure 150, and the second carrier 160 may be removed. The second semiconductor chip 180 may be mounted on an upper substrate 181 on the second redistribution structure 150 by wire bonding. The upper substrate 181 may include pads 182 on an upper surface thereof. The pads 182 may be electrically connected to wirings (e.g, the first wiring pattern 152 and the second wiring pattern 154) in the second redistribution structure 150. The second redistribution structure 150 may be electrically connected to the second semiconductor chip 180 by a pad 182 and a wire 184. An adhesive may be disposed on a lower surface of the second semiconductor chip 180 and may fix the second semiconductor chip 180 to the second redistribution structure 150. In FIG. 14, the second semiconductor chip 180 is shown as being mounted by the wire bonding, but the present inventive concept is not limited thereto, and in another exemplary embodiment, the second semiconductor chip 180 may be connected to the second redistribution structure 150 by being flip-chip bonded thereto. The second carrier 160 may be separated from the second redistribution structure 150 by heat by irradiating laser light or UV light.

The second semiconductor chip 180 may function differently from the first semiconductor chip 130. For example, the first semiconductor chip 130 may be a logic chip such as an application processor, and the second semiconductor chip 180 may be a memory chip such as a dynamic random access memory (DRAM), a static random access memory (SRAM), a NAND memory, or the like.

Referring to FIG. 15, a process of forming an encapsulant 185 surrounding an upper surface of the second redistribution structure 150 and the second semiconductor chip 180 is performed. An upper surface of the encapsulant 185 may be positioned at a higher level than an upper surface of the second semiconductor chip 180, and the encapsulant 185 may cover the exposed portions of the second semiconductor chip 180 and the wire 184. The encapsulant 185 may be a resin including an epoxy or polyimide.

The semiconductor package 100 according to one exemplary embodiment of the present inventive concept may be completed by covering the second semiconductor chip 180 with the encapsulant 185. The semiconductor package 100 may include a lower package 10 and an upper package 20. The lower package 10 may include the first redistribution structure 110, the first semiconductor chip 130, the conductive pillar 125, the encapsulant 142, and the second redistribution structure 150. The upper package 20 may include the second semiconductor chip 180, the upper substrate 181, the wire 184, and the encapsulant 185.

The second semiconductor chip 180 is shown in FIGS. 14 and 15 as being connected through the second redistribution structure 150, but the present inventive concept is not limited thereto. In another exemplary embodiment, solder balls disposed below the second semiconductor chip 180 may be physically and electrically connected to the conductive pillar 125.

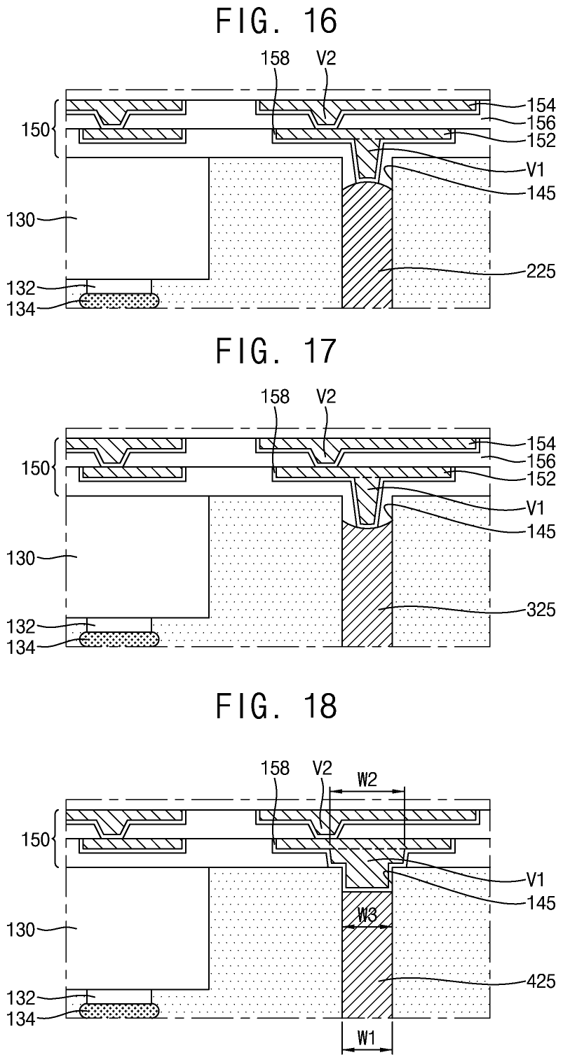

FIGS. 16 to 18 are cross-sectional views of a semiconductor package according to another embodiment of the present inventive concept.

In one exemplary embodiment, the upper portion of the conductive pillar 125 may be nonuniformly etched during the process of partially etching upper portions of the plurality of conductive pillars 125 to form the opening OP on the upper portion of the encapsulant 142. For example, while the wet etching process is performed, the conductive pillar 125 may be isotropically etched so that the upper surface of the conductive pillar 125 may not be flat.

Referring to FIG. 16, an upper surface of a conductive pillar 225 may be formed to be convex in a vertical direction.

Further, referring to FIG. 17, an upper surface of a conductive pillar 325 may be formed to be concave in the vertical direction.

Referring to FIG. 18, a connection via V1 may completely fill an inside of a opening OP. In one exemplary embodiment, a width W2 of the upper surface of the connection via V1 may be greater than a width W1 of a conductive pillar 425 and/or a width W1 of the upper surface of the conductive pillar 425. A width W3 of a lower surface of the connection via V1 may have the same value as the width W1 of the conductive pillar 425 and/or the width W2 of the upper surface of the conductive pillar 425. With respect to the connection via V1, the width W2 of its upper surface may be greater than the width W3 of its lower surface. Widths herein may refer to a corresponding dimension in the horizontal direction of a particular cross sectional view and need not correspond to the shortest dimension of the relevant structure.

Although not shown, in another exemplary embodiment, the width W2 of the upper surface of the connection via V1 may have the same value as the width W1 of the conductive pillar 125, and the width W3 of the lower surface of the connection via V1 may be less than the width W1 of the conductive pillar 425.

FIGS. 19 to 22 are cross-sectional views that are shown according to a process sequence for describing a method of manufacturing the semiconductor package according to one exemplary embodiment of the present inventive concept.

Each of FIGS. 19 to 22 is another exemplary embodiment corresponding to each of FIGS. 4 to 7, respectively. Referring to FIG. 19, a sacrificial layer 522 may be disposed on a conductive pillar 122. As shown in FIG. 3, the conductive pillar 122 and the sacrificial layer 522 may be sequentially formed along a mask pattern 120 formed on a first redistribution structure 110. The sacrificial layer 522 may include a material different from the conductive pillar 122. For example, the sacrificial layer 522 may be Ni or Au, or a combination thereof.

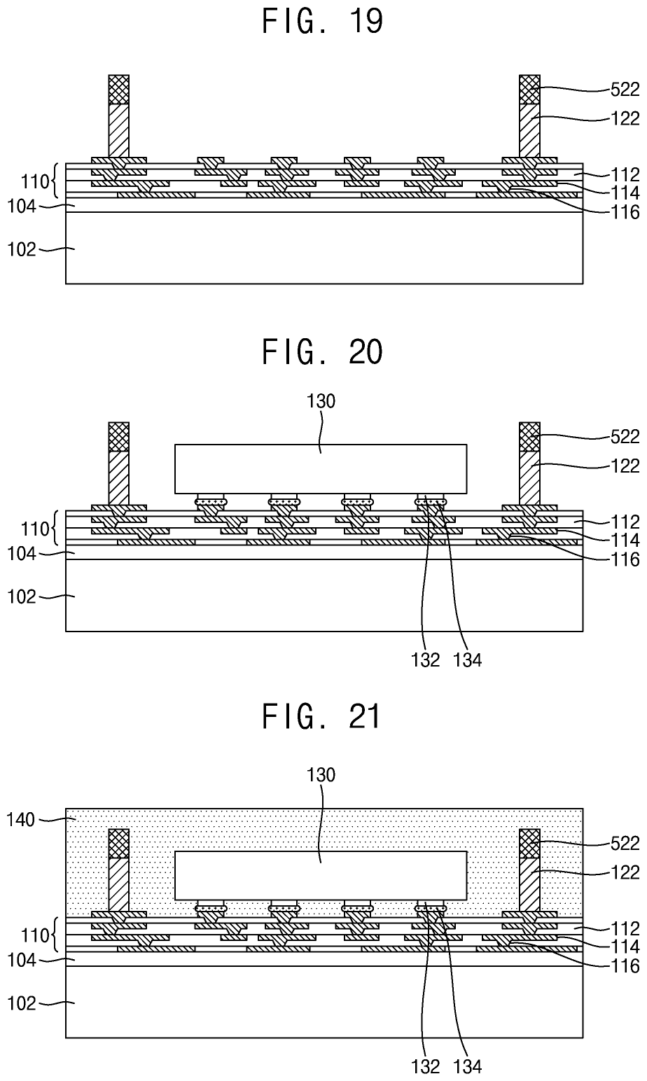

Referring to FIG. 20, a first semiconductor chip 130 may be mounted on the first redistribution structure 110. Referring to FIG. 21, an encapsulant 140 covering an upper surface of the first redistribution structure 110, a plurality of conductive pillars 122, and the first semiconductor chip 130 may be formed.

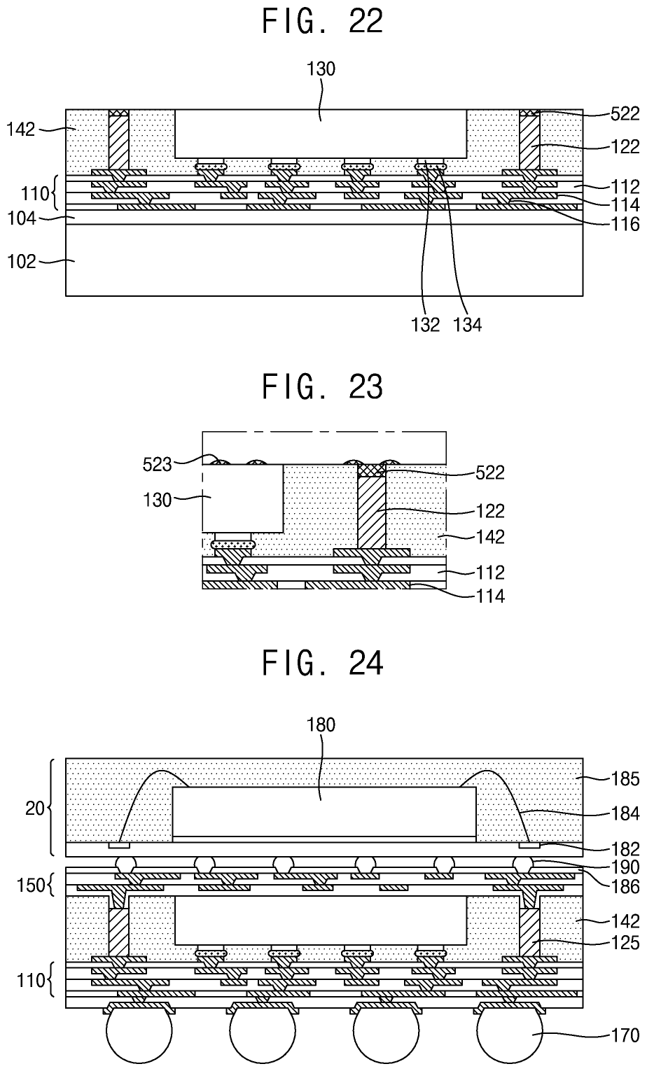

Referring to FIG. 22, an upper surface of the first semiconductor chip 130 may be exposed by a grinding process. For example, the first semiconductor chip 130, the encapsulant 140, and the sacrificial layer 522 may be ground. An upper surface of the sacrificial layer 522 may be positioned at the same level as the upper surface of the first semiconductor chip 130 and an upper surface of an encapsulant 142. The conductive pillar 122 disposed below the sacrificial layer 522 may not be etched while the grinding process is performed.

FIG. 23 is a partially enlarged view of the semiconductor package shown in FIG. 22. Referring to FIG. 23, residues 523 generated by the grinding process may be disposed on the resultant of FIG. 22. A portion of the sacrificial layer 522 that is separated from the sacrificial layer 522 may be formed as the residues 523. The residues 523 may be disposed on the upper surface of the conductive pillar 122, the first semiconductor chip 130, or the encapsulant 142.

The sacrificial layer 522 and the residues 523 may be removed (see FIG. 9). For example, the sacrificial layer 522 and the residues 523 may be removed by selective etching. The sacrificial layer 522 may be removed to form a opening OP on an upper portion of the encapsulant 142. As illustrated, an inner side surface 145 of the opening OP corresponds physically to a side portion of the encapsulant 142, and a lower surface of the opening OP corresponds physically to an upper surface of the conductive pillar 122. The upper surface of the conductive pillar 122 may be positioned at a lower level than an upper surface of the first semiconductor chip 130 and the upper surface of the encapsulant 142.

In one exemplary embodiment, the sacrificial layer 522 and the residues 523 may be removed by wet etching using a wet etchant. For example, the wet etchant may be FeCl₃ or HNO₃ or a combination thereof. The conductive pillar 122, the first semiconductor chip 130, and the encapsulant 142 may not be etched in the above-described etching process. In the method of manufacturing the semiconductor package according to one exemplary embodiment of the present inventive concept, the conductive pillar 122 is not etched when the residues 523 are removed, so that the heights of the plurality of conductive pillars 122 may be controlled.

FIG. 24 is a cross-sectional view of a semiconductor package according to another embodiment of the present inventive concept.

Referring to FIG. 24, an upper package 20 may be connected to a second redistribution structure 150 by a connection member 186. The connection member 186 may be disposed between the second redistribution structure 150 and the upper substrate 181, and may be electrically connected to the pad 182 through wirings in the upper substrate 181. A lower surface of the upper package 20 may be spaced apart from an upper surface of the second redistribution structure 150. A second semiconductor chip 180 may be mounted on the second redistribution structure 150 after the upper package 20 is completed by covering the second semiconductor chip 180 with an encapsulant 185. The encapsulant 185 may cover an upper surface and one side surface of the second semiconductor chip 180. The connection member 186 may be electrically connected to the second semiconductor chip 180. For example, the connection members 186 may be electrically connected to the second semiconductor chip 180 through a pad 182. Further, the connection member 186 may be electrically connected to a first semiconductor chip 130 through the second redistribution structure 150. The connection member 186 may include the same material as an external connection member 170.

According to the embodiments of the present inventive concept, a problem of lowering reliability can be prevented by removing residues on a semiconductor chip and an encapsulant.

It should be understood that the indefinite articles “a” or “an” carries the meaning of “one or more” or “at least one” in the embodiments of the present inventive concept throughout the specification.

While the embodiments of the present inventive concept have been described with reference to the accompanying drawings, it should be understood by those skilled in the art that various modifications may be made without departing from the scope of the present inventive concept and without changing essential features thereof. Therefore, the above-described embodiments should be considered in a descriptive sense only and not for purposes of limitation.

1. A semiconductor package comprising:
a first redistribution structure;
a first semiconductor chip disposed on the first redistribution structure;
a conductive pillar disposed on the first redistribution structure and being adjacent to the first semiconductor chip;
an first encapsulant covering an upper surface of the first redistribution structure, a lower surface and side surfaces of the first semiconductor chip, and side surfaces of the conductive pillar, the first encapsulant having an upper surface having an opening formed therein, the opening exposing an upper surface of the conductive pillar; and
a second redistribution structure disposed on the first encapsulant and connected to the conductive pillar, wherein the second redistribution structure comprises a wiring pattern and a connection via, the connection via filling at least a portion of the opening and connected to the conductive pillar, andwherein the opening expose a portion of the first redistribution structure.

2. The semiconductor package of claim 1, wherein a height from an upper surface of the first redistribution structure to an upper surface of the conductive pillar is lower than a height from the upper surface of the first redistribution structure to an upper surface of the first semiconductor chip.

3. The semiconductor package of claim 1, wherein the conductive pillar has a concave upper surface.

4. The semiconductor package of claim 1, wherein the conductive pillar has a convex upper surface.

5. The semiconductor package of claim 1, further comprising a second semiconductor chip disposed on the second redistribution structure and including a pad on an upper surface thereof,
wherein the second semiconductor chip is electrically connected to the conductive pillar through the pad.

6. The semiconductor package of claim 1, wherein the second redistribution structure comprises a connection via connected to the conductive pillar and a wiring pattern disposed on the connection via.

7. The semiconductor package of claim 6, wherein the connection via includes a lower surface having a width that is equal to a width of the conductive pillar.

8. The semiconductor package of claim 7, wherein the connection via includes an upper surface having a width that is greater than a width of the conductive pillar.

9. The semiconductor package of claim 1, further comprising a plurality of bumps disposed on a lower surface of the first semiconductor chip, wherein the first encapsulant covers side surfaces of each of the plurality of bumps.

10. The semiconductor package of claim 1, further comprising a second semiconductor chip formed on the second redistribution structure.

11. The semiconductor package of claim 1, further comprising an upper package formed on the second redistribution structure and connection member on a lower surface of the second package, the connection member electrically connecting the upper package and the second redistribution structure, and
wherein the upper package comprises a second semiconductor chip and a second encapsulant covering an upper surface and side surfaces of the second semiconductor chip, and a lower surface of the upper package is spaced apart from an upper surface of the second redistribution structure.

12. A semiconductor package comprising:
a first redistribution structure;
a first semiconductor chip disposed on the first redistribution structure;
a plurality of conductive pillars disposed on the first redistribution structure and being adjacent to the first semiconductor chip;
an encapsulant covering an upper surface of the first redistribution structure, the first semiconductor chip, and side surfaces of the plurality of conductive pillars, the encapsulant having an upper surface having openings formed therein, the openings exposing upper surfaces of the plurality of conductive pillars; and
a second redistribution structure disposed on the encapsulant and connected to the plurality of conductive pillars,
wherein the second redistribution structure comprises wiring patterns and connection vias formed on the wiring pattern, the connection vias connected to the plurality of conductive pillars, and
a height from an upper surface of the first redistribution structure to an upper surface of the encapsulant is higher than a height from the upper surface of the first redistribution structure to an upper surface of at least one of the plurality of the conductive pillars.

13. The semiconductor package of claim 12, wherein each connection via has an upper surface with a width that is smaller than a corresponding width of a conductive pillar of the plurality of conductive pillars.

14. The semiconductor package of claim 12, wherein the upper surface of the encapsulant is coplanar with an upper surface of the first semiconductor chip.

15. The semiconductor package of claim 12, further comprising an upper substrate and a second semiconductor chip mounted on the upper substrate, the upper substrate disposed on the second redistribution structure and including pads on an upper surface thereof,
wherein the second semiconductor chip is electrically connected to a corresponding conductive pillar of the plurality of conductive pillars through the pads.

16. The semiconductor package of claim 15, further comprising a second encapsulant covers side surfaces and an upper surface of the second semiconductor chip.

17-21. (canceled)
